(19) United States
(12) Patent Application Publication
(10) Pub. No.: US 2025/0324775 A1
(43) Pub. Date: Oct. 16, 2025

(54) SEMICONDUCTOR LIGHT-RECEIVING DEVICE

(71) Applicant: SUMITOMO ELECTRIC INDUSTRIES, LTD., Osaka (JP)

(72) Inventors: Takashi KATO, Osaka-shi (JP); Yasuhiro IGUCHI, Osaka-shi (JP); Kazutoshi NATSUME, Osaka-shi (JP)

(73) Assignee: SUMITOMO ELECTRIC INDUSTRIES, LTD, Osaka (JP)

(21) Appl. No.: 19/172,737

(22) Filed: Apr. 8, 2025

(30) Foreign Application Priority Data
Apr. 10, 2024 (JP) 2024-063409

(51) Int. Cl. H10F 30/222; H10F 77/124; H10F 77/14

(52) U.S. Cl. CPC H10F 30/222; H10F 77/1248; H10F 77/146

(57) ABSTRACT

A semiconductor light-receiving device includes an indium phosphide substrate, a first III-V compound semiconductor layer of a first conductivity type, a second III-V compound semiconductor layer of a second conductivity type, a light absorbing layer provided between the first III-V compound semiconductor layer and the second III-V compound semiconductor layer and including a III-V compound semiconductor, and a third III-V compound semiconductor layer provided between the light absorbing layer and the second III-V compound semiconductor layer, the third III-V compound semiconductor layer being non-doped. The first III-V compound semiconductor layer is provided between the indium phosphide substrate and the light absorbing layer. The third III-V compound semiconductor layer has a band gap energy larger than a maximum value of a band gap energy of the III-V compound semiconductor included in the light absorbing layer.

### CROSS REFERENCE TO RELATED APPLICATIONS

This application claims priority based on Japanese Patent Application No. 2024-063409 filed on Apr. 10, 2024, and the entire contents of the Japanese patent application are incorporated herein by reference.

### TECHNICAL FIELD

The present disclosure relates to a semiconductor light-receiving device.

### BACKGROUND

Non-patent literature (Jingyi Wang, et al, “InP-Based Broadband Photodetectors With InGaAs/GaAsSb Type-II Superlattice” IEEE Electron Device Letters, Vol.43, No.5, 2022, pp. 757-760) discloses a photodetector including an indium phosphide (InP) substrate. An n-type indium gallium arsenide (InGaAs) layer, a superlattice layer, a light absorbing layer, a p-type indium aluminum arsenide (InAlAs) layer, a p-type aluminum arsenic antimonide (AlAsSb) layer, and a p-type InGaAs layer are sequentially provided on the InP substrate. The superlattice layer includes an InGaAs layer and a gallium arsenide antimonide (GaAsSb) layer. The light absorbing layer is a non-doped InGaAs layer. The AlAsSb layer functions as an electron barrier layer.

### SUMMARY

A semiconductor light-receiving device according to an aspect of the present disclosure includes an indium phosphide substrate, a first III-V compound semiconductor layer of a first conductivity type, a second III-V compound semiconductor layer of a second conductivity type, a light absorbing layer provided between the first III-V compound semiconductor layer and the second III-V compound semiconductor layer and including a III-V compound semiconductor, and a third III-V compound semiconductor layer provided between the light absorbing layer and the second III-V compound semiconductor layer, the third III-V compound semiconductor layer being non-doped. The first III-V compound semiconductor layer is provided between the indium phosphide substrate and the light absorbing layer. The third III-V compound semiconductor layer has a band gap energy larger than a maximum value of a band gap energy of the III-V compound semiconductor included in the light absorbing layer.

### BRIEF DESCRIPTION OF THE DRAWINGS

FIG. 1 is a cross-sectional view schematically showing a semiconductor light-receiving device according to an embodiment.

FIG. 2 is a cross-sectional view schematically showing a light absorbing layer included in the semiconductor light-receiving device of FIG. 1.

FIG. 3 is a cross-sectional view schematically showing a grading super-lattice layer included in the semiconductor light-receiving device of FIG. 1.

FIG. 4 is a cross-sectional view schematically showing a semiconductor light-receiving device according to another embodiment.

FIG. 5 is a diagram showing a structure example of a part of a semiconductor light-receiving device of a second experiment.

FIG. 6 is a graph showing an example of a relationship between a layer number and an energy at an upper end of a valence band in a semiconductor light-receiving device of a second experiment.

FIG. 7 is a diagram showing an example of a part of an energy band diagram of a light absorbing layer in a semiconductor light-receiving device of a second experiment.

FIG. 8 is a diagram showing an example of a part of an energy band diagram of a grading super-lattice layer in a semiconductor light-receiving device of a second experiment.

FIG. 9 is a graph showing an example of an energy band diagram of a semiconductor light-receiving device of a first experiment.

FIG. 10 is a graph showing an example of an energy band diagram of a semiconductor light-receiving device of a second experiment.

FIG. 11 is a graph showing an example of an energy band diagram of a semiconductor light-receiving device of a third experiment.

FIG. 12 is a graph showing an example of the distribution of an electron concentration and a hole concentration in a semiconductor light-receiving device of a first experiment.

FIG. 13 is a graph showing an example of the distribution of an electron concentration and a hole concentration in a semiconductor light-receiving device of a second experiment.

### DETAILED DESCRIPTION

The present disclosure provides a semiconductor light-receiving device capable of reducing dark current.

### [Description of Embodiments of Present Disclosure]

First, embodiments of the present disclosure will be listed and described.

(1) A semiconductor light-receiving device includes an indium phosphide substrate, a first III-V compound semiconductor layer of a first conductivity type, a second III-V compound semiconductor layer of a second conductivity type, a light absorbing layer provided between the first III-V compound semiconductor layer and the second III-V compound semiconductor layer and including a III-V compound semiconductor, and a third III-V compound semiconductor layer provided between the light absorbing layer and the second III-V compound semiconductor layer, the third III-V compound semiconductor layer being non-doped. The first III-V compound semiconductor layer is provided between the indium phosphide substrate and the light absorbing layer. The third III-V compound semiconductor layer has a band gap energy larger than a maximum value of a band gap energy of the III-V compound semiconductor included in the light absorbing layer.

In the semiconductor light-receiving device, the third III-V compound semiconductor layer has a large band gap energy. Thus, an energy of a carrier trap level that may be formed in the third III-V compound semiconductor layer is increased, and thus carriers are less likely to be thermally excited to the carrier trap level. As a result, tunnel current due to the carrier trap level can be reduced, and thus dark current can be reduced.

(2) In the above (1), the semiconductor light-receiving device may further include a fourth III-V compound semiconductor layer of a second conductivity type provided between the third III-V compound semiconductor layer and the second III-V compound semiconductor layer.

(3) In the above (2), the fourth III-V compound semiconductor layer may have a thickness smaller than a thickness of the third III-V compound semiconductor layer.

In this case, the accumulation of holes in the light absorbing layer can be reduced.

(4) In any one of the above (1) to (3), the third III-V compound semiconductor layer may include a ternary III-V compound semiconductor containing aluminum.

In this case, the crystallinity of the third III-V compound semiconductor layer is improved as compared with a quaternary III-V compound semiconductor.

(5) In any one of the above (1) to (4), the third III-V compound semiconductor layer may have a thickness of 300 nm or more.

(6) In any one of the above (1) to (5), the semiconductor light-receiving device may further include at least one fifth III-V compound semiconductor layer provided between the light absorbing layer and the third III-V compound semiconductor layer, the at least one fifth III-V compound semiconductor layer being non-doped. An upper end of a valence band of the at least one fifth III-V compound semiconductor layer may have an energy between an energy at an upper end of a valence band of the light absorbing layer and an energy at an upper end of a valence band of the third III-V compound semiconductor layer.

In this case, holes in the light absorbing layer are likely to flow into the third III-V compound semiconductor layer through the fifth III-V compound semiconductor layer. Thus, the accumulation of holes in the light absorbing layer can be reduced.

(7) In the above (6), the at least one fifth III-V compound semiconductor layer may have a quantum well structure.

In this case, the crystallinity of the fifth III-V compound semiconductor layer is improved as compared with the bulk semiconductor.

(8) In the above (6) or (7), the at least one fifth III-V compound semiconductor layer may include a plurality of fifth III-V compound semiconductor layers, each being non-doped. Each of the plurality of fifth III-V compound semiconductor layers may include a sixth III-V compound semiconductor layer including a III-V compound semiconductor material that is a same as a III-V compound semiconductor material included in the third III-V compound semiconductor layer. A thickness of the sixth III-V compound semiconductor layer may monotonically increase from the light absorbing layer toward the third III-V compound semiconductor layer.

### [Details of Embodiments of Present Disclosure]

Hereinafter, embodiments of the present disclosure will be described in detail with reference to the accompanying drawings. In the description of the drawings, the same or equivalent elements are denoted by the same reference numerals, and redundant description thereof will be omitted.

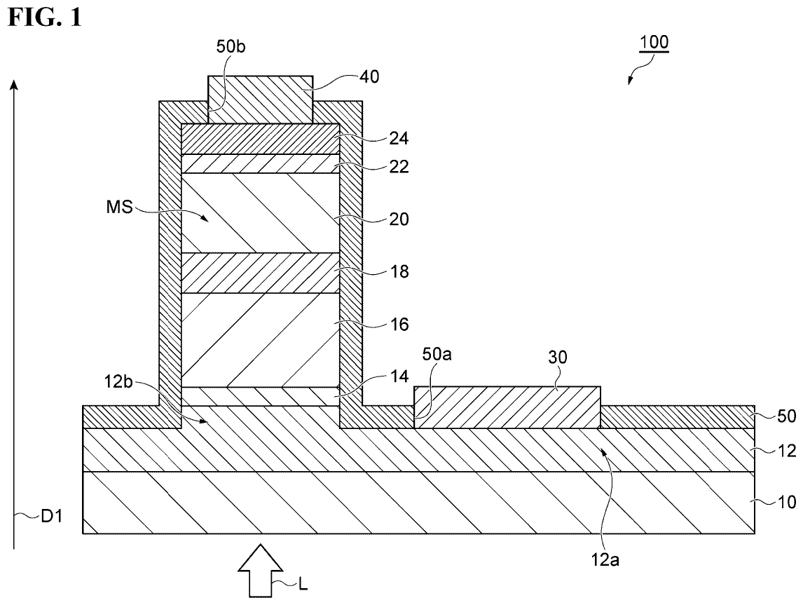

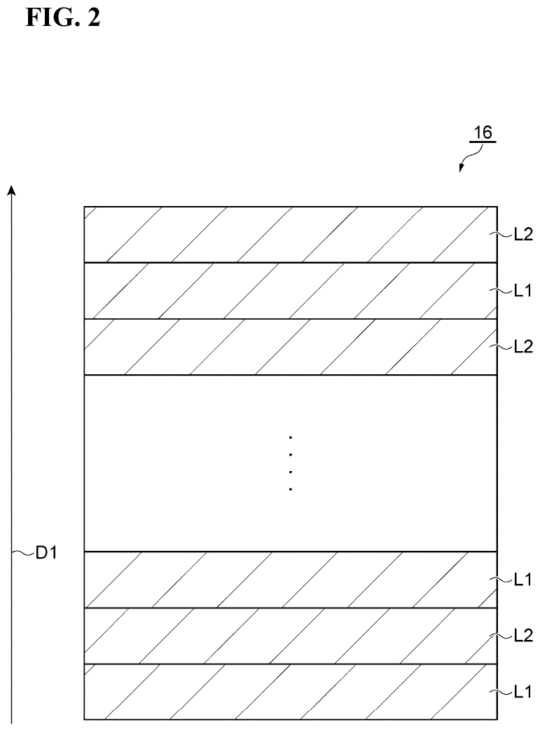

FIG. 1 is a cross-sectional view schematically showing a semiconductor light-receiving device according to an embodiment. FIG. 2 is a cross-sectional view schematically showing a light absorbing layer included in the semiconductor light-receiving device of FIG. 1. A semiconductor light-receiving device 100 shown in FIG. 1 is, for example, a photodiode. Semiconductor light-receiving device 100 includes an indium phosphide (InP) substrate 10, a first III-V compound semiconductor layer 12 of a first conductivity type, a light absorbing layer 16, a non-doped third III-V compound semiconductor layer 20, and a second III-V compound semiconductor layer 24 of a second conductivity type. The first conductivity type is, for example, an n-type. The second conductivity type is a conductivity type opposite to the first conductivity type, and is, for example, a p-type. Light absorbing layer 16 is provided between first III-V compound semiconductor layer 12 and second III-V compound semiconductor layer 24. First III-V compound semiconductor layer 12 is provided between InP substrate 10 and light absorbing layer 16. Third III-V compound semiconductor layer 20 is provided between light absorbing layer 16 and second III-V compound semiconductor layer 24.

Semiconductor light-receiving device 100 may further include at least one of an III-V compound semiconductor layer 14, a grading super-lattice layer 18, and a fourth III-V compound semiconductor layer 22 of the second conductivity type. III-V compound semiconductor layer 14 is provided between first III-V compound semiconductor layer 12 and light absorbing layer 16. Grading super-lattice layer 18 is provided between light absorbing layer 16 and third III-V compound semiconductor layer 20. Fourth III-V compound semiconductor layer 22 is provided between third III-V compound semiconductor layers 20 and second III-V compound semiconductor layer 24. In a first direction D1, InP substrate 10, first III-V compound semiconductor layer 12, III-V compound semiconductor layer 14, light absorbing layer 16, grading super-lattice layer 18, third III-V compound semiconductor layer 20, fourth III-V compound semiconductor layer 22, and second III-V compound semiconductor layer 24 may be sequentially disposed. The layers adjacent to each other in first direction DI may be in contact with each other. First direction D1 may be a direction from InP substrate 10 toward second III-V compound semiconductor layer 24. First direction D1 may be orthogonal to a main surface of InP substrate 10. First direction D1 may be a thickness direction of light absorbing layer 16. First direction D1 may be a crystal growth direction.

First III-V compound semiconductor layer 12 may include a body portion 12a and a protruding portion 12b on body portion 12a. III-V compound semiconductor layer 14, light absorbing layer 16, grading super-lattice layer 18, third III-V compound semiconductor layer 20, fourth III-V compound semiconductor layer 22, and second III-V compound semiconductor layer 24 are provided in this order on protruding portion 12b. Protruding portion 12b, III-V compound semiconductor layer 14, light absorbing layer 16, grading super-lattice layer 18, third III-V compound semiconductor layer 20, fourth III-V compound semiconductor layer 22, and second III-V compound semiconductor layer 24 form a mesa MS.

Semiconductor light-receiving device 100 may include an insulating film 50 covering mesa MS and body portion 12a. Insulating film 50 may be a silicon oxide film. Insulating film 50 may have an opening 50a on body portion 12a and an opening 50b on a top surface of mesa MS. An electrode 30 connected to body portion 12a is provided in opening 50a. An electrode 40 connected to second III-V compound semiconductor layer 24 is provided in opening 50b. A reverse bias voltage may be applied between electrode 30 and electrode 40.

Semiconductor light-receiving device 100 can detect an incident light L. Incident light L may be visible light or infrared light having a wavelength of 0.4 μm to 4 μm. Incident light L may proceed in first direction D1. Incident light L may be incident on light absorbing layer 16 through InP substrate 10. Semiconductor light-receiving device 100 may have a cut-off wavelength (absorption edge wavelength) of 2 μm to 4 μm. Semiconductor light-receiving device 100 can be used in a spectroscopic system of a gas analyzer, an imaging system, or an optical communication system.

InP substrate 10 may be a semi-insulating substrate. InP substrate 10 may include InP doped with iron. The main surface of InP substrate 10 may be a (100) plane. First III-V compound semiconductor layer 12 is provided on the main surface of InP substrate 10.

First III-V compound semiconductor layer 12 may be a contact layer. First III-V compound semiconductor layer 12 may be a gallium indium arsenide (GaₓIn₁₋ₓAs or GaInAs) layer of a first conductivity type. The x is a gallium (Ga) composition. The x is more than zero and less than one. The x may be from 0.46 to 0.49. A dopant concentration in first III-V compound semiconductor layer 12 may be from 5×10¹⁷ cm⁻³ to 3×10¹⁹ cm⁻³. A thickness of body portion 12a of first III-V compound semiconductor layer 12 may be from 0.05 μm to 3 μm.

III-V compound semiconductor layer 14 may be a non-doped GaₓIn₁₋ₓAs layer. The x is a gallium (Ga) composition. The x is more than zero and less than one. The x may be from 0.46 to 0.49. A thickness of III-V compound semiconductor layer 14 may be from 0.01 μm to 0.2 μm.

Light absorbing layer 16 includes an III-V compound semiconductor. Light absorbing layer 16 may be a non-doped III-V compound semiconductor layer. In this specification, “non-doped” means that a dopant is not intentionally doped. Thus, the “non-doped” layer may have an n-type carrier concentration of less than 1×10¹⁵ cm⁻³ or may have a p-type carrier concentration of less than 1×10¹⁵ cm⁻³. Light absorbing layer 16 may have a quantum well structure such as a type-II superlattice structure or may be a bulk semiconductor layer. As shown in FIG. 2, the superlattice structure of light absorbing layer 16 may include a non-doped GaₓIn₁₋ₓAs (or GaInAs) layer L1 and a non-doped gallium arsenide antimonide (GaAs_{y}Sb_{1-y} or GaAsSb) layer L2. The x is a gallium (Ga) composition. The x is more than zero and less than one. The x may be from 0.4 to 0.7. The y is an arsenic (As) composition. The y may be from 0.2 to 0.6. GaₓIn₁₋ₓAs layer L1 and GaAs_{y}Sb_{1-y} layer L2 may be alternately arranged along first direction D1. GaₓIn₁₋ₓAs layer L1 may be positioned to form a lower surface of light absorbing layer 16 closest to first III-V compound semiconductor layer 12. Thus, GaₓIn₁₋ₓAs layer L1 can be formed on the semiconductor layer with good crystallinity. GaAs_{y}Sb_{1-y} layer L2 may be positioned to form an upper surface of light absorbing layer 16 closest to second III-V compound semiconductor layer 24. Thus, the semiconductor layer can be formed on GaAs_{y}Sb_{1-y} layer L2 with good crystallinity. The number of pairs (periods) of GaₓIn₁₋ₓAs layer L1 and GaAs_{y}Sb_{1-y} layer L2 may be from 200 to 400. A thickness of GaₓIn₁₋ₓAs layer L1 may be from 3 nm to 8 nm. A thickness of GaAs_{y}Sb_{1-y} layer L2 may be from 3 nm to 8 nm. The thicknesses of GaAs_{y}Sb_{1-y} layer L2 may be the same as or may be different from the thicknesses of GaₓIn₁₋ₓAs layer L1.

Third III-V compound semiconductor layer 20 may be a cap layer. When light absorbing layer 16 has a bulk III-V compound semiconductor, third III-V compound semiconductor layer 20 has a band gap energy larger than a band gap energy of light absorbing layer 16. When light absorbing layer 16 has a quantum well structure such as a type-II superlattice structure, third III-V compound semiconductor layer 20 has a band gap energy larger than a band gap energy of the superlattice structure. Third III-V compound semiconductor layer 20 may have a band gap energy larger than a band gap energy (0.73 eV) of Ga_{0.47}In_{0.53}As. Third III-V compound semiconductor layer 20 may have a band gap energy of 1 eV or more. Third III-V compound semiconductor layer 20 may include a ternary III-V compound semiconductor or may include a quaternary III-V compound semiconductor. When third III-V compound semiconductor layer 20 includes the ternary III-V compound semiconductor, the crystallinity of third III-V compound semiconductor layer 20 is improved as compared to a quaternary III-V compound semiconductor. Third III-V compound semiconductor layer 20 may include aluminum. Third III-V compound semiconductor layer 20 may include aluminum indium arsenide (Al_{z}In_{1-z}As or AlInAs), aluminum indium arsenide antimonide (AlInAsSb), or aluminum gallium arsenide antimonide (AlGaAsSb). The z is an aluminum (Al) composition. The z is more than zero and less than one. The z may be from 0.4 to 0.7. Third III-V compound semiconductor layer 20 may have a thickness of 300 nm or more, and may have a thickness of 1000 nm or less.

Fourth III-V compound semiconductor layer 22 may be a cap layer. Fourth III-V compound semiconductor layer 22 may include a III-V compound semiconductor material that is the same as a III-V compound semiconductor material included in third III-V compound semiconductor layer 20. Fourth III-V compound semiconductor layer 22 may be an AlInAs layer of a second conductivity type. Fourth III-V compound semiconductor layer 22 may include beryllium (Be) as a dopant. A dopant concentration in fourth III-V compound semiconductor layer 22 may be from 1×10¹⁷ cm⁻³ to 1×10¹⁹ cm⁻³. Fourth III-V compound semiconductor layer 22 may have a thickness smaller than a thickness of third III-V compound semiconductor layer 20. Fourth III-V compound semiconductor layer 22 may have a thickness of 50 nm or more, and may have a thickness of 500 nm or less.

Second III-V compound semiconductor layer 24 may be a contact layer. Second III-V compound semiconductor layer 24 may be a GaₓIn₁₋ₓAs (or GaInAs) layer of a second conductivity type. The x is a gallium (Ga) composition. The x is more than zero and less than one. The x may be from 0.46 to 0.49. Second III-V compound semiconductor layer 24 may have a dopant concentration higher than the dopant concentration of fourth III-V compound semiconductor layer 22. The dopant concentration in second III-V compound semiconductor layer 24 may be from 5×10¹⁷ cm⁻³ to 3×10¹⁹ cm⁻³. A thickness of second III-V compound semiconductor layer 24 may be from 0.1 μm to 3 μm.

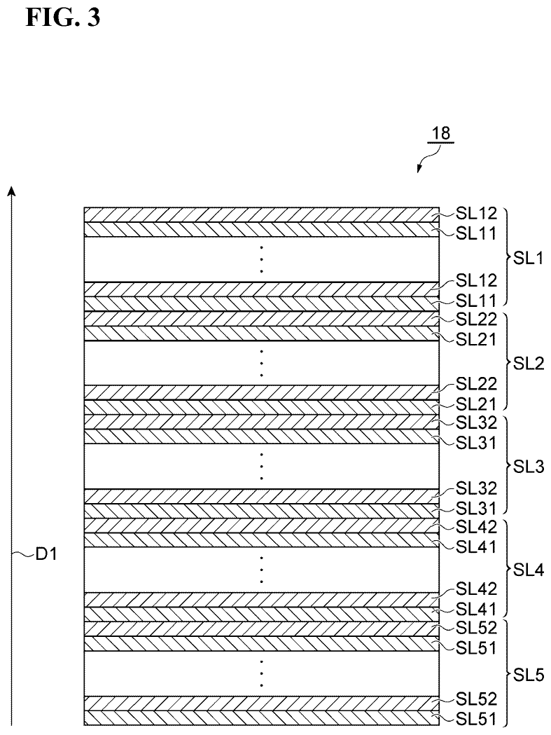

FIG. 3 is a cross-sectional view schematically showing a grading super-lattice layer included in the semiconductor light-receiving device of FIG. 1. As shown in FIG. 3, grading super-lattice layer 18 may include a plurality of a non-doped fifth III-V compound semiconductor layers SL1 to SL5, or may be a bulk semiconductor layer. The plurality of fifth III-V compound semiconductor layers SL1 to SL5 are sequentially disposed in a direction opposite to first direction D1. Fifth III-V compound semiconductor layer SL1 may be in contact with third III-V compound semiconductor layer 20. Fifth III-V compound semiconductor layer SL5 may be in contact with light absorbing layer 16. Grading super-lattice layer 18 may include at least one of the plurality of fifth III-V compound semiconductor layers SL1 to SL5. Each of fifth III-V compound semiconductor layers SL1 to SL5 may have a quantum well structure such as a superlattice structure. When each of fifth III-V compound semiconductor layers SL1 to SL5 has a quantum well structure, the crystallinity of each of fifth III-V compound semiconductor layers SL1 to SL5 is improved compared to a bulk semiconductor.

Fifth III-V compound semiconductor layer SL1 may include a plurality of III-V compound semiconductor layers SL11 and a plurality of III-V compound semiconductor layers SL12. III-V compound semiconductor layer SL11 and III-V compound semiconductor layer SL12 are alternately disposed in first direction D1. III-V compound semiconductor layer SL11 is positioned to form a lower surface of fifth III-V compound semiconductor layer SL1 closest to light absorbing layer 16. III-V compound semiconductor layer SL 12 is positioned to form an upper surface of fifth III-V compound semiconductor layer SL1 closest to second III-V compound semiconductor layer 24.

Fifth III-V compound semiconductor layer SL2 may include a plurality of III-V compound semiconductor layers SL21 and a plurality of III-V compound semiconductor layers SL22. III-V compound semiconductor layer SL21 and III-V compound semiconductor layer SL22 are alternately disposed in first direction D1. III-V compound semiconductor layer SL21 is positioned to form a lower surface of fifth III-V compound semiconductor layer SL2 closest to light absorbing layer 16. III-V compound semiconductor layer SL22 is positioned to form an upper surface of fifth III-V compound semiconductor layer SL2 closest to second III-V compound semiconductor layer 24.

Fifth III-V compound semiconductor layer SL3 may include a plurality of III-V compound semiconductor layers SL31 and a plurality of III-V compound semiconductor layers SL32. III-V compound semiconductor layer SL31 and III-V compound semiconductor layer SL32 are alternately disposed in first direction D1. III-V compound semiconductor layer SL31 is positioned to form a lower surface of fifth III-V compound semiconductor layer SL3 closest to light absorbing layer 16. III-V compound semiconductor layer SL32 is positioned to form an upper surface of fifth III-V compound semiconductor layer SL3 closest to second III-V compound semiconductor layer 24.

Fifth III-V compound semiconductor layer SL4 may include a plurality of III-V compound semiconductor layers SL41 and a plurality of III-V compound semiconductor layers SL42. III-V compound semiconductor layer SL41 and III-V compound semiconductor layer SL42 are alternately disposed in first direction D1. III-V compound semiconductor layer SL41 is positioned to form a lower surface of fifth III-V compound semiconductor layer SL4 closest to light absorbing layer 16. III-V compound semiconductor layer SL42 is positioned to form an upper surface of fifth III-V compound semiconductor layer SL4 closest to second III-V compound semiconductor layer 24.

Fifth III-V compound semiconductor layer SL5 may include a plurality of III-V compound semiconductor layers SL51 and a plurality of III-V compound semiconductor layers SL52. III-V compound semiconductor layer SL51 and III-V compound semiconductor layer SL52 are alternately disposed in first direction D1. III-V compound semiconductor layer SL51 is positioned to form a lower surface of fifth III-V compound semiconductor layer SL5 closest to light absorbing layer 16. III-V compound semiconductor layer SL52 is positioned to form an upper surface of fifth III-V compound semiconductor layer SL5 closest to second III-V compound semiconductor layer 24

An upper end of a valence band of each of fifth III-V compound semiconductor layers SL1 to SL5 may have an energy between an energy at an upper end of a valence band of light absorbing layer 16 and an energy at an upper end of a valence band of third III-V compound semiconductor layer 20. The energy at the upper end of the valence band of each of fifth III-V compound semiconductor layers SL1 to SL5 may be sequentially decreased in first direction D1. The energy at the upper end of the valence band of fifth III-V compound semiconductor layer SL1 may be lower than the energy at the upper end of the valence band of fifth III-V compound semiconductor layer SL2. The energy at the upper end of the valence band of fifth III-V compound semiconductor layer SL2 may be lower than the energy at the upper end of the valence band of fifth III-V compound semiconductor layer SL3. The energy at the upper end of the valence band of fifth III-V compound semiconductor layer SL3 may be lower than the energy at the upper end of the valence band of fifth III-V compound semiconductor layer SL4. The energy at the upper end of the valence band of fifth III-V compound semiconductor layer SL4 may be lower than the energy at the upper end of the valence band of fifth III-V compound semiconductor layer SL5. In first direction D1, the upper end of the valence band of each of fifth III-V compound semiconductor layers SL1 to SL5 may decrease in a stepped manner.

An energy Ec at a lower end of a conduction band and an energy Ev at the upper end of the valence band of each of III-V compound semiconductor layers SL1 to SL5 are obtained from band calculation of each of SLs (superlattices).

Each of III-V compound semiconductor layers SL11, SL21, SL31, SL41, and SL51 (sixth III-V compound semiconductor layer) may include a III-V compound semiconductor material that is the same as the III-V compound semiconductor material included in third III-V compound semiconductor layer 20. An example of each of III-V compound semiconductor layers SL11, SL21, SL31, SL41 or SL51 include AlInAs, AlInAsSb and AlGaAsSb. The thicknesses of III-V compound semiconductor layers SL11, SL21, SL31, SL41, and SL51 may monotonically increase from light absorbing layer 16 toward third III-V compound semiconductor layer 20.

An example of the III-V compound semiconductor included in each of III-V compound semiconductor layers SL12, SL22, SL32, SL42, and SL52 include GaAsSb. The thicknesses of III-V compound semiconductor layers SL12, SL22, SL32, SL42, and SL52 may monotonically decrease from light absorbing layer 16 toward third III-V compound semiconductor layer 20.

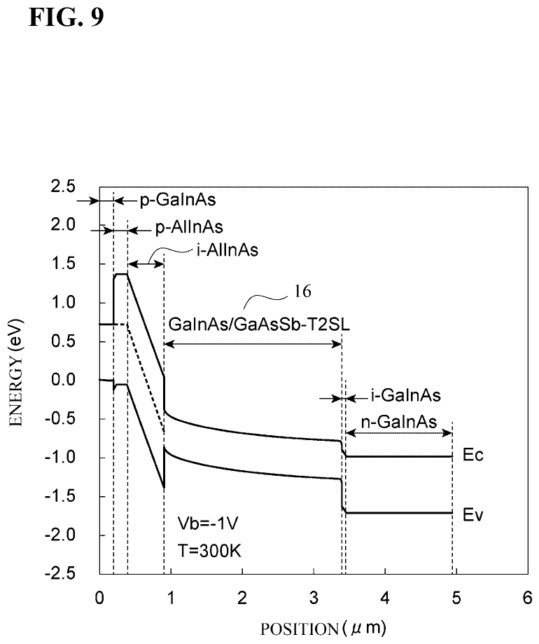

In semiconductor light-receiving device 100, third III-V compound semiconductor layer 20 has a large band gap energy. Thus, an energy of a carrier trap level that may be formed in third III-V compound semiconductor layer 20 is increased (refer to FIG. 9). Thus, carriers are less likely to be thermally excited to the carrier trap level. As a result, tunnel current due to the carrier trap level can be reduced, and thus dark current can be reduced. The carrier trap level is positioned between the upper end of the valence band and the lower end of the conduction band. The carrier trap level may be formed by a lattice defect formed in the sidewall of mesa MS by etching.

When fourth III-V compound semiconductor layer 22 has a thickness smaller than a thickness of third III-V compound semiconductor layer 20, the accumulation of holes in light absorbing layer 16 can be reduced.

When semiconductor light-receiving device 100 includes grading super-lattice layer 18, holes in light absorbing layer 16 are likely to flow into third III-V compound semiconductor layer 20 through fifth III-V compound semiconductor layers SL1 to SL5. Thus, the accumulation of holes in light absorbing layer 16 can be reduced.

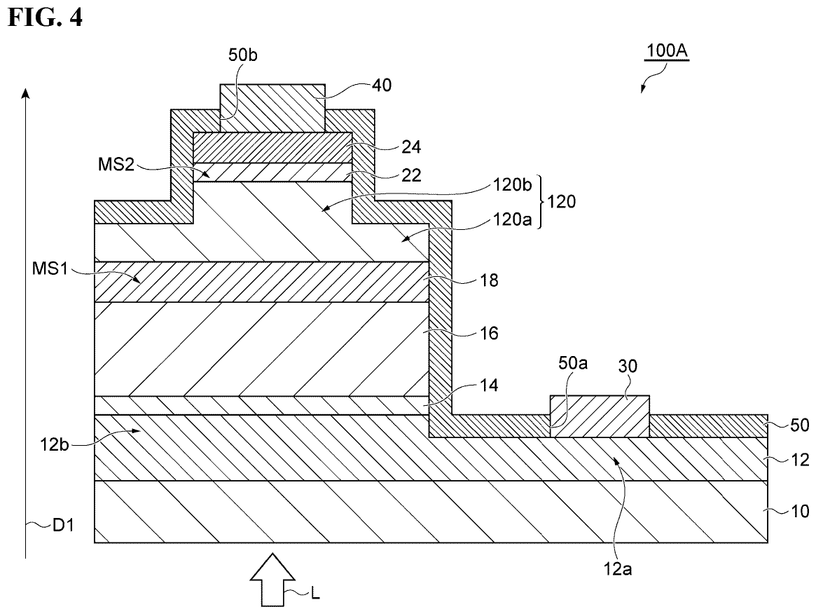

FIG. 4 is a cross-sectional view schematically showing a semiconductor light-receiving device according to another embodiment. A semiconductor light-receiving device 100A shown in FIG. 4 may have the same configuration as semiconductor light-receiving device 100 of FIG. 1 except that a third III-V compound semiconductor layer 120 is provided instead of third III-V compound semiconductor layer 20.

Third III-V compound semiconductor layer 120 includes a body portion 120a and a protruding portion 120b on body portion 120a. Protruding portion 12b of first III-V compound semiconductor layer 12, III-V compound semiconductor layer 14, light absorbing layer 16, grading super-lattice layer 18, and body portion 120a of third III-V compound semiconductor layer 120 form a mesa MS1. Mesa MS1 is provided on InP substrate 10. Protruding portion 120b of third III-V compound semiconductor layer 120, fourth III-V compound semiconductor layer 22, and second III-V compound semiconductor layer 24 form a mesa MS2. Mesa MS2 is provided on mesa MS1. In a direction orthogonal to first direction D1, mesa MS2 has a maximum dimension smaller than a maximum dimension of mesa MS1. A step is formed between mesa MS1 and mesa MS2.

In semiconductor light-receiving device 100A, third III-V compound semiconductor layer 120 has a large band gap energy. Thus, an energy of a carrier trap level that may be formed in third III-V compound semiconductor layer 120 is increased. Thus, carriers are less likely to be thermally excited to the carrier trap level. As a result, tunnel current due to the carrier trap level can be reduced, and thus dark current can be reduced. Further, in semiconductor light-receiving device 100A, the distance from the central axis of mesa MS1 extending along first direction DI to the sidewall of mesa MS1 can be increased. The electrical characteristics of semiconductor light-receiving device 100A mainly depend on an electric field applied at or near the central axis of mesa MS1. Thus, in semiconductor light-receiving device 100A, influence of the lattice defect that may be formed in the sidewall of mesa MSI on the electrical characteristics of semiconductor light-receiving device 100A can be reduced.

Various experiments conducted for evaluating semiconductor light-receiving devices 100 and 100A will be described below. The experiments described below are not intended to limit the invention.

### (First Experiment)

A semiconductor light-receiving device of a first experiment has the following configuration similar to semiconductor light-receiving device 100 except that grading super-lattice layer 18 is not provided.
InP substrate 10: Fe-doped InP substrate,
first III-V compound semiconductor layer 12: n-type GaInAs layer,

III-V compound semiconductor layer 14: i-type GaInAs layer,
light absorbing layer 16: a type-II superlattice structure including GaₓIn₁₋ₓAs (x =0.468) layers and GaAs_{y}Sb_{1-y} (y =0.513) layers, 237 periods,
third III-V compound semiconductor layer 20: i-type AlInAs layer, 500 nm thick,
fourth III-V compound semiconductor layer 22: p-type AlInAs layer, 200 nm thick, and
second III-V compound semiconductor layer 24: p-type GaInAs layer.

### (Second Experiment)

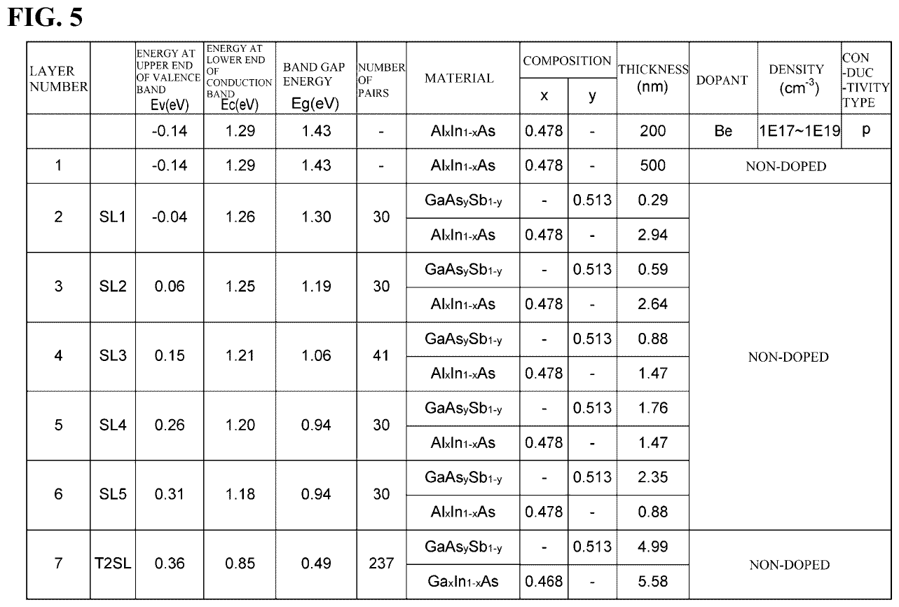

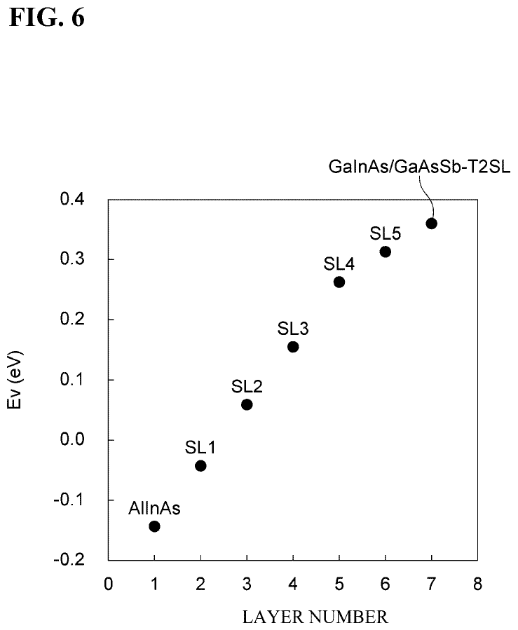

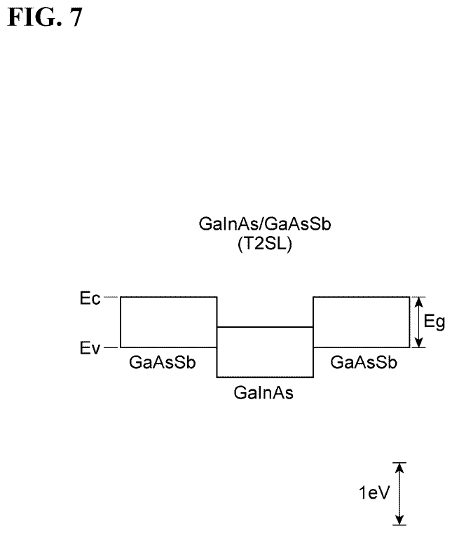

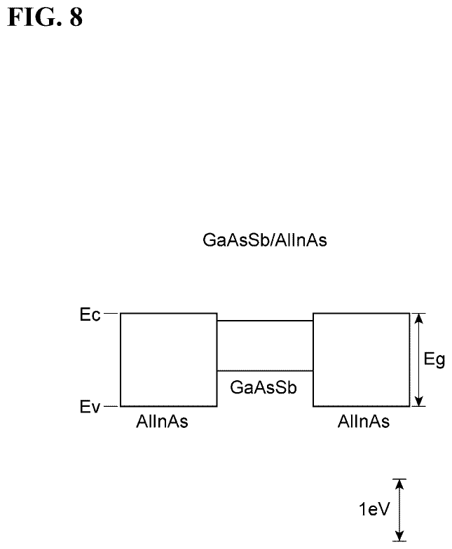

A semiconductor light-receiving device of a second experiment has the same configuration as the semiconductor light-receiving device of the first experiment except that grading super-lattice layer 18 is provided. FIG. 5 shows a structure example of a part of a semiconductor light-receiving device of the second experiment. The structure example shown in FIG. 5 corresponds to light absorbing layer 16, grading super-lattice layer 18, third III-V compound semiconductor layer 20, and fourth III-V compound semiconductor layer 22. In FIG. 5, the energy Ec at the lower end of the conduction band and the energy Ev at the upper end of the valence band were calculated using the Ev of Ga_{0.47}In_{0.53}As as 0 eV. FIG. 6 is a graph showing an example of a relationship between the layer number and the energy at the upper end of the valence band shown in FIG. 5. FIG. 7 and FIG. 8 show examples of parts of energy band diagrams of the light absorbing layer and the grading super-lattice layer, respectively.

### (Third Experiment)

A semiconductor light-receiving device of a third experiment has the same configuration as the semiconductor light-receiving device of the first experiment except that an i-type GaInAs layer and a p-type GaInAs layer are provided instead of the i-type AlInAs layer (third III-V compound semiconductor layer 20) and the p-type AlInAs layer (fourth III-V compound semiconductor layer 22), respectively.

### (First Experiment Results)

For each of the semiconductor light-receiving devices of the first experiment to the third experiment, an energy band diagram of is prepared by simulation. A temperature T used in the simulation is 300 Kelvin (K). A bias voltage Vb applied to the semiconductor light-receiving devices is −1 V. The results of the simulation are shown in FIG. 9 to FIG. 11.

FIG. 9 to FIG. 11 are graphs showing examples of energy band diagrams of semiconductor light-receiving devices of the first experiment to the third experiment, respectively. In each graph of FIG. 9 to FIG. 11, the horizontal axis indicates the position (μm) in a thickness direction (direction opposite to first direction D1) of light absorbing layer 16. The position of the upper surface of the p-type GaInAs layer (second III-V compound semiconductor layer 24) corresponds to zero. The vertical axis indicates energy (eV). In each graph, Ec indicates an energy at a lower end of the conduction band, and Ev indicates an energy at an upper end of the valence band.

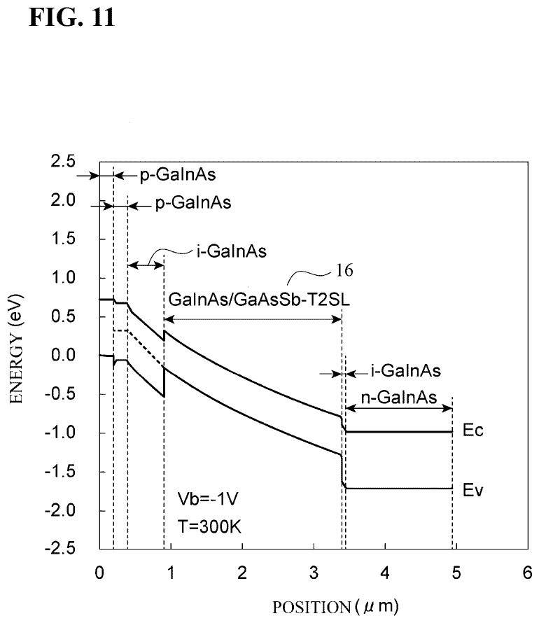

As shown in FIG. 9, in the first experiment, a carrier trap level shown by a dashed line is formed in the i-type AlInAs layer and the p-type AlInAs layer. As shown in FIG. 11, in the third experiment, a carrier trap level shown by a dashed line is formed in the i-type GaInAs layer and the p-type GaInAs layer. As can be seen from FIG. 9 and FIG. 11, the energy of the carrier trap level in the first experiment is higher than the energy of the carrier trap level in the third experiment. Thus, in the first experiment, carriers are less likely to be thermally excited to the carrier trap level than in the third experiment. As a result, tunnel current due to the carrier trap level can be reduced, and thus dark current can be reduced.

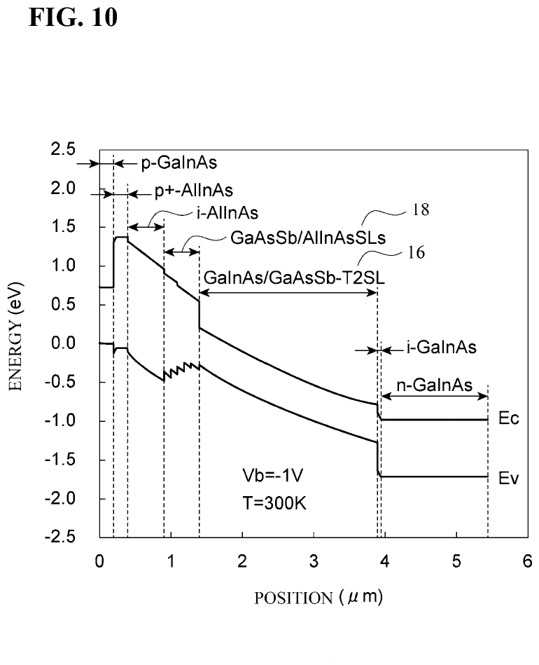

As shown in FIG. 9, in the first experiment, between light absorbing layer 16 and the i-type AlInAs layer, the difference between the energy Ev at the upper end of the valence band of the i-type AlInAs layer and the energy Ev at the upper end of the valence band of light absorbing layer 16 is relatively large. As a result, holes in the valence band of light absorbing layer 16 are less likely to flow into the i-type AlInAs layer. Thus, the accumulation of holes in light absorbing layer 16 increases. As shown in FIG. 10, in the second experiment, grading super-lattice layer 18 is provided between light absorbing layer 16 and the i-type AlInAs layer. The energy Ev at the upper end of the valence band of grading super-lattice layer 18 decreases in a stepped manner from light absorbing layer 16 toward the i-type AlInAs layer. As a result, holes in the valence band of light absorbing layer 16 are likely to flow into the i-type AlInAs layer through grading super-lattice layer 18. Thus, the accumulation of holes in light absorbing layer 16 can be reduced.

### (Second Experiment Results)

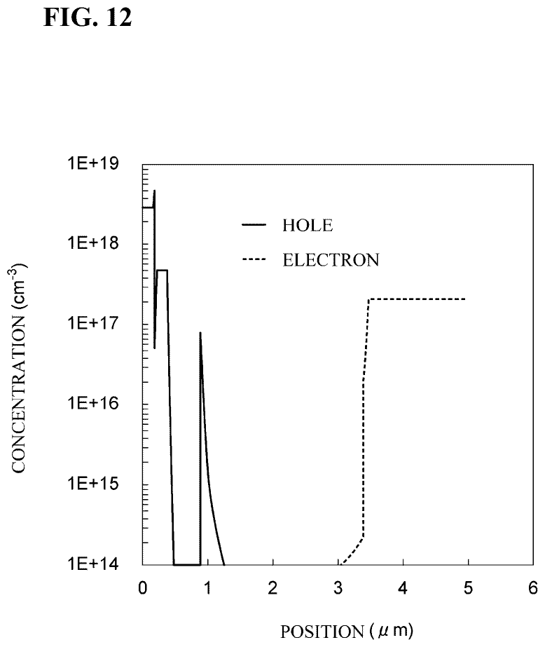

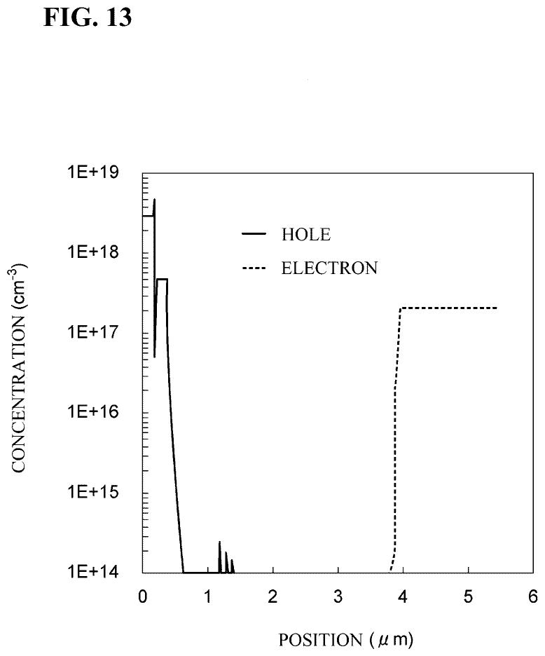

For the semiconductor light-receiving devices of the first experiment and the second experiment, an electron concentration and a hole concentration were calculated by simulation. The results of the simulation are shown in FIG. 12 and FIG. 13.

FIG. 12 and FIG. 13 are graphs showing examples of the distributions of the electron concentration and the hole concentration in the semiconductor light-receiving devices of the first experiment and the second experiment, respectively. In each graph of FIG. 12 and FIG. 13, the horizontal axis indicates the same position (μm) as the horizontal axis of each graph of FIG. 9 to FIG. 11. The vertical axis indicates the electron concentration (cm⁻³) or the hole concentration (cm⁻³).

As shown in FIG. 12, in the first experiment, the peak of the hole concentration was about 1×10¹⁷ cm⁻³ at the position of 1 μm. This indicates that the accumulation of holes are large in the vicinity of the boundary between light absorbing layer 16 and the i-type AlInAs layer. As shown in FIG. 13, in the second experiment, the peak of the hole concentration was about 3×10¹⁴ cm⁻³ at the position of 1 μm. This indicates that the accumulation of holes are small in the vicinity of the boundary between light absorbing layer 16 and the i-type AlInAs layer. Thus, it can be understood that grading super-lattice layer 18 can reduce the accumulation of holes in light absorbing layer 16.

Although the exemplary embodiments of the present invention have been described in detail, the present invention is not limited to the above-described embodiments.

The embodiments disclosed herein are to be considered in all respects as illustrative and not restrictive. The scope of the present invention is defined by the appended claims rather than the foregoing description, and is intended to include all modifications within the scope and meaning equivalent to the appended claims.

What is claimed is:

1. A semiconductor light-receiving device comprising:
an indium phosphide substrate;
a first III-V compound semiconductor layer of a first conductivity type;
a second III-V compound semiconductor layer of a second conductivity type;
a light absorbing layer provided between the first III-V compound semiconductor layer and the second III-V compound semiconductor layer and including a III-V compound semiconductor; and
a third III-V compound semiconductor layer provided between the light absorbing layer and the second III-V compound semiconductor layer, the third III-V compound semiconductor layer being non-doped,
wherein the first III-V compound semiconductor layer is provided between the indium phosphide substrate and the light absorbing layer, and
wherein the third III-V compound semiconductor layer has a band gap energy larger than a maximum value of a band gap energy of the III-V compound semiconductor included in the light absorbing layer.

2. The semiconductor light-receiving device according to claim 1, further comprising:
a fourth III-V compound semiconductor layer of a second conductivity type provided between the third III-V compound semiconductor layer and the second III-V compound semiconductor layer.

3. The semiconductor light-receiving device according to claim 2, wherein the fourth III-V compound semiconductor layer has a thickness smaller than a thickness of the third III-V compound semiconductor layer.

4. The semiconductor light-receiving device according to claim 1, wherein the third III-V compound semiconductor layer includes a ternary III-V compound semiconductor containing aluminum.

5. The semiconductor light-receiving device according to claim 1, wherein the third III-V compound semiconductor layer has a thickness of 300 nm or more.

6. The semiconductor light-receiving device according to claim 1, further comprising:
at least one fifth III-V compound semiconductor layer provided between the light absorbing layer and the third III-V compound semiconductor layer, the at least one fifth III-V compound semiconductor layer being non-doped,
wherein an upper end of a valence band of the at least one fifth III-V compound semiconductor layer has an energy between an energy at an upper end of a valence band of the light absorbing layer and an energy at an upper end of a valence band of the third III-V compound semiconductor layer.

7. The semiconductor light-receiving device according to claim 6, wherein the at least one fifth III-V compound semiconductor layer has a quantum well structure.

8. The semiconductor light-receiving device according to claim 6,
wherein the at least one fifth III-V compound semiconductor layer includes a plurality of fifth III-V compound semiconductor layers, each being non-doped,
wherein each of the plurality of fifth III-V compound semiconductor layers includes a sixth III-V compound semiconductor layer including a III-V compound semiconductor material that is a same as a III-V compound semiconductor material included in the third III-V compound semiconductor layer, and
wherein a thickness of the sixth III-V compound semiconductor layer monotonically increases from the light absorbing layer toward the third III-V compound semiconductor layer.
